(19) United States
(12) Patent Application Publication
(10) Pub. No.: US 2016/0211434 A1
(43) Pub. Date: Jul. 21, 2016

(54) THERMOELECTRIC CONVERSION MATERIAL, THERMOELECTRIC CONVERSION ELEMENT AND METHOD FOR MANUFACTURING THERMOELECTRIC CONVERSION ELEMENT

(71) Applicant: FUJIFILM Corporation, Tokyo (JP)

(72) Inventor: Takeyoshi KANO, Ashigarakami-gun (JP)

(73) Assignee: FUJIFILM Corporation, Tokyo (JP)

(21) Appl. No.: 15/086,569

(22) Filed: Mar. 31, 2016

Related U.S. Application Data
(63) Continuation of application No. PCT/JP2014/076057, filed on Sep. 30, 2014.

(30) Foreign Application Priority Data
Oct. 1, 2013 (JP) 2013-206360

(51) Int. Cl. H01L 35/24; C08F 220/68; C09D 133/14; C09D 5/24

(52) U.S. Cl. CPC H01L 35/24; C09D 5/24; C08F 220/68; C09D 133/14

(57) ABSTRACT

A thermoelectric conversion material containing (a) a nanocarbon material and (b) a dispersing agent having an anchoring group to the nanocarbon material and a steric repulsive group and having a decomposable group between the anchoring group and the steric repulsive group, a thermoelectric conversion element manufactured using the same, a method for manufacturing the same, a dispersing agent of a nanocarbon material consisting of a polymer compound including a repeating unit represented by General Formula (1A) below and a repeating unit represented by General Formula (1B) below, and a nanocarbon material dispersion containing the same:

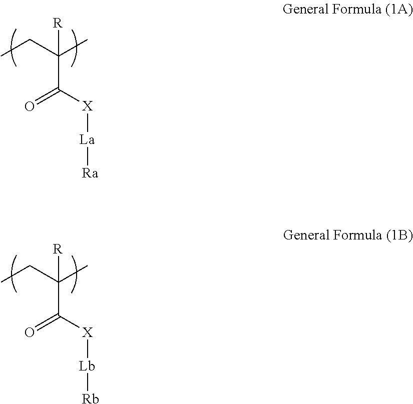

In General Formula (1A), Ra represents an aromatic group, an alicyclic group, an alkyl group, a hydroxyl group, a thiol group, an amino group, an ammonium group, or a carboxyl group. La represents a divalent group having an acetal structure, a tertiary alkyl ester structure, or a peroxide structure. R represents a hydrogen atom or an alkyl group having 1 to 4 carbon atoms. X represents an oxygen atom or —NH—.

In General Formula (1B), Rb represents a monovalent group derived from a polyalkylene oxide compound, a poly(meth)acrylate compound, a polysiloxane compound, a polyacrylonitrile compound, or a polystyrene compound, a monovalent group obtained by combining the above-described compounds, or an alkyl group having 5 or more carbon atoms. Lb represents a single bond or a divalent linking group. R and X are identical to those in General Formula (1A).

### CROSS-REFERENCE TO RELATED APPLICATIONS

This application is a Continuation of PCT International Application No. PCT/JP2014/076057 filed on Sep. 30, 2014, which claims priority under 35 U.S.C. §119 (a) to Japanese Patent Application No. 2013-206360 filed on Oct. 1, 2013. Each of the above applications is hereby expressly incorporated by reference, in its entirety, into the present application.

### BACKGROUND OF THE INVENTION

1. Field of the Invention

The present invention relates to a thermoelectric conversion material, a thermoelectric conversion element, and a method for manufacturing a thermoelectric conversion element. In addition, the invention relates to a dispersing agent of a nanocarbon material and a nanocarbon material dispersion containing the same.

2. Description of the Related Art

Thermoelectric conversion materials that can mutually convert heat energy and electric energy are used in thermoelectric power generating elements and in thermoelectric conversion elements such as Peltier devices. Thermoelectric power generation achieved by applying a thermoelectric conversion material or a thermoelectric conversion element enables direct conversion from heat energy to electric power, does not require any moving parts, and is used in wrist watches that are operated by body temperature, as well as in power supplies for remote areas and power supplies used in space.

As one of indexes that evaluate the thermoelectric conversion performance of a thermoelectric conversion element, there is a dimensionless figure of merit ZT (hereinafter, in some cases, simply referred to as the figure of merit ZT). The figure of merit ZT is represented by Equation (A) below, and important factors for the enhancement of the thermoelectric conversion performance are the increase in the thermoelectromotive force S per absolute temperature (hereinafter, in some cases, referred to as the thermoelectromotive force) and electrical conductivity σ and the reduction of thermal conductivity κ.

Figure of merit ZT=S²·σ·T/κ (A)

In Equation (A), S (V/K): Thermoelectromotive force per absolute temperature (Seebeck coefficient)
σ (S/m): Electrical conductivity
κ (W/mK): Thermal conductivity
T (K): Absolute temperature

The thermoelectric conversion materials require favorable thermoelectric conversion performance, and thermoelectric conversion materials that have been mainly put into practical use at the moment are inorganic materials. However, inorganic materials need to undergo a complicated step to be processed into thermoelectric conversion elements, are expensive, and, in some cases, include harmful substances.

On the other hand, organic thermoelectric conversion elements can be manufactured at relatively low costs, and processes for forming films and the like are also easy, and thus, in recent years, active studies have been underway, and organic thermoelectric conversion materials and thermoelectric conversion elements manufactured using the organic thermoelectric conversion materials have been reported. In order to increase the figure of merit ZT of thermoelectric conversion, there is a demand for an organic material having a high Seebeck coefficient, high electric conductivity, and low thermal conductivity.

As organic materials having excellent electroconductive properties, carbon nanotubes are known. However, carbon nanotubes easily aggregate and have low dispersibility. Therefore, attempts are made to increase the dispersibility of carbon nanotubes. For example, JP2013-95821A proposes a composition containing an electroconductive polymer together with a carbon nanotube as a composition having excellent dispersibility of a carbon nanotube and proposes the use of the composition as a thermoelectric conversion material.

### SUMMARY OF THE INVENTION

An object of the present invention is to provide a thermoelectric conversion material which contains a nanocarbon material such as a carbon nanotube and a dispersing agent of the nanocarbon material, has favorable dispersibility of the nanocarbon material, and is excellent in terms of electrical conductivity and thermoelectromotive force and a thermoelectric conversion element manufactured using the same. Furthermore, another object of the invention is to provide a method for manufacturing the thermoelectric conversion element.

In addition, still another object of the invention is to provide a dispersing agent of a nanocarbon material and a composition containing the dispersing agent and a nanocarbon material.

First, the present inventors studied dispersing agents of nanocarbon materials in consideration of the above-described objects. As a result, it was found that a particular compound which has an anchoring group to a nanocarbon material and a steric repulsive group in the molecule and has a decomposable group between the anchoring group and the steric repulsive group is capable of favorably dispersing a nanocarbon material in a solvent. Furthermore, it was found that a composition containing the compound and a nanocarbon material exhibits excellent thermoelectric conversion performance and is useful as a thermoelectric conversion material. The invention has been completed on the basis of the above-described finding.

That is, according to the invention, the following means are provided:

<1> A thermoelectric conversion material containing (a) a nanocarbon material; and (b) a dispersing agent having an anchoring group to the nanocarbon material and a steric repulsive group and having a decomposable group between the anchoring group and the steric repulsive group.

<2> The thermoelectric conversion material according to <1>, in which (b) the dispersing agent is a polymer compound including a repeating unit represented by General Formula (1A) below and a repeating unit represented by General Formula (1B) below:

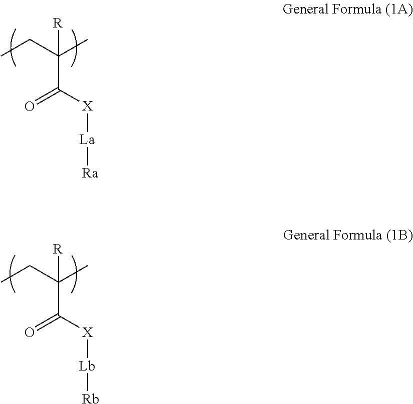

In General Formula (1A), Ra represents an aromatic group, an alicyclic group, an alkyl group, a hydroxyl group, a thiol group, an amino group, an ammonium group, or a carboxyl group. La represents a divalent group having an acetal structure, a tertiary alkyl ester structure, or a peroxide structure. R represents a hydrogen atom or an alkyl group having 1 to 4 carbon atoms. X represents an oxygen atom or —NH—.

In General Formula (1B), Rb represents a monovalent group derived from a polyalkylene oxide compound, a poly(meth)acrylate compound, a polysiloxane compound, a polyacrylonitrile compound, or a polystyrene compound, a monovalent group obtained by combining the above-described compounds, or an alkyl group having 5 or more carbon atoms. Lb represents a single bond or a divalent linking group. R and X are identical to those in General Formula (1A).

<3> The thermoelectric conversion material according to <1>, in which (b) the dispersing agent is a compound represented by General Formula (2) below:

RaₙLₘRb General Formula (2)

In General Formula (2), Ra represents an aromatic group, an alicyclic group, an alkyl group, a hydroxyl group, a thiol group, an amino group, an ammonium group, or a carboxyl group. Rb represents a monovalent group derived from a polyalkylene oxide compound, a poly(meth)acrylate compound, a polysiloxane compound, a polyacrylonitrile compound, or a polystyrene compound, a monovalent group obtained by combining the above-described compounds, or an alkyl group having 5 or more carbon atoms. L represents a (n+m)-valent organic group having an acetal structure, a tertiary alkyl ester structure, or a peroxide structure. Each of n and m independently represents an integer of 1 to 4.

<4> The thermoelectric conversion material according to <2> or <3>, in which, in General Formula (1A) or General Formula (2), Ra is an aromatic group.

<5> The thermoelectric conversion material according to any one of <2> to <4>, in which, in General Formula (1B) or General Formula (2), Rb is a monovalent group derived from a poly(meth)acrylate compound.

<6> The thermoelectric conversion material according to any one of <1> to <5>, containing a solvent.

<7> A thermoelectric conversion element having, on a base material, a first electrode, a thermoelectric conversion layer, and a second electrode, in which the thermoelectric conversion layer is formed using the thermoelectric conversion material according to any one of <1> to <6>.

<8> A method for manufacturing a thermoelectric conversion element including a step of forming a thermoelectric conversion layer on a base material by applying the thermoelectric conversion material according to any one of <1> to <6>; and a step of decomposing a dispersing agent in the formed thermoelectric conversion layer.

<9> The method for manufacturing a thermoelectric conversion element according to <8>, in which, in the decomposition step, a heating treatment of the thermoelectric conversion layer is carried out.

<10> A nanocarbon material dispersion containing (a) a nanocarbon material, (b1) a polymer compound including a repeating unit represented by General Formula (1A) below and a repeating unit represented by General Formula (1B) below, and (c) a solvent:

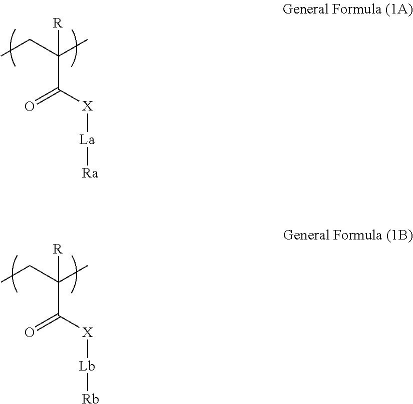

In General Formula (1A), Ra represents an aromatic group, an alicyclic group, an alkyl group, a hydroxyl group, a thiol group, an amino group, an ammonium group, or a carboxyl group. La represents a divalent group having an acetal structure, a tertiary alkyl ester structure, or a peroxide structure. R represents a hydrogen atom or an alkyl group having 1 to 4 carbon atoms. X represents an oxygen atom or —NH—.

In General Formula (1B), Rb represents a monovalent group derived from a polyalkylene oxide compound, a poly(meth)acrylate compound, a polysiloxane compound, a polyacrylonitrile compound, or a polystyrene compound, a monovalent group obtained by combining the above-described compounds, or an alkyl group having 5 or more carbon atoms. Lb represents a single bond or a divalent linking group. R and X are identical to those in General Formula (1A).

<11> A dispersing agent of a nanocarbon material made of a polymer compound including a repeating unit represented by General Formula (1A) below and a repeating unit represented by General Formula (1B) below:

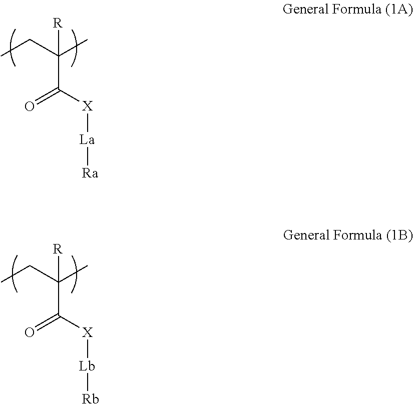

In General Formula (1A), Ra represents an aromatic group, an alicyclic group, an alkyl group, a hydroxyl group, a thiol group, an amino group, an ammonium group, or a carboxyl group. La represents a divalent group having an acetal structure, a tertiary alkyl ester structure, or a peroxide structure. R represents a hydrogen atom or an alkyl group having 1 to 4 carbon atoms. X represents an oxygen atom or —NH—.

In General Formula (1B), Rb represents a monovalent group derived from a polyalkylene oxide compound, a poly(meth)acrylate compound, a polysiloxane compound, a polyacrylonitrile compound, or a polystyrene compound, a monovalent group obtained by combining the above-described compounds, or an alkyl group having 5 or more carbon atoms. Lb represents a single bond or a divalent linking group. R and X are identical to those in General Formula (1A).

In the invention, a numerical value range described using “to” means a range including the values described before and after “to” as the lower limit value and the upper limit value.

In addition, in the invention, when an xxx group is mentioned as a substituent, the xxx group may have an arbitrary substituent. In addition, in case in which there are a plurality of groups indicated by the same reference signal, the groups may be identical to or different from each other.

Repeating structures illustrated by individual formulae do not have to be exactly the same repeating structures and may be different repeating structures as long as the repeating structures belong to the range represented by the formulae. For example, in case in which repeating structures have an alkyl group, repeating structures illustrated by individual formulae may be all repeating structures having a methyl group or may include repeating structures having a different alkyl group, for example, an ethyl group in addition to repeating structures having a methyl group.

The thermoelectric conversion material of the invention has favorable dispersibility of a nanocarbon material and is suitable for forming a thermoelectric conversion layer using a coating method. In the thermoelectric conversion layer formed using the material, since the nanocarbon material is uniformly dispersed, and the nanocarbon material particles are appropriately adjacent to each other, excellent electroconductive properties and thermoelectromotive force are exhibited. In addition, the thermoelectric conversion element of the invention comprising the thermoelectric conversion layer exhibits excellent thermoelectric conversion performance.

In the manufacturing method of the invention, a thermoelectric conversion element having excellent thermoelectric conversion performance can be obtained.

Furthermore, the dispersing agent of the invention is capable of improving the dispersibility of a nanocarbon material, particularly, a carbon nanotube. The composition of the invention containing the dispersing agent and a nanocarbon material is a dispersion in which the nanocarbon material is favorably dispersed and is suitable for a film-forming process by means of a coating method.

The above-described and other characteristics and advantages of the invention will be more clarified by the following description with appropriate reference to the accompanying drawings.

### BRIEF DESCRIPTION OF THE DRAWINGS

FIG. 1 is a view schematically illustrating a section of an example of a thermoelectric conversion element of the present invention. The arrow in FIG. 1 indicates the direction of a temperature difference applied during the use of the element.

FIG. 2 is a view schematically illustrating a section of another example of the thermoelectric conversion element of the invention. The arrow in FIG. 2 indicates the direction of a temperature difference applied during the use of the element.

### DESCRIPTION OF THE PREFERRED EMBODIMENTS

The present invention provides a thermoelectric conversion material, a thermoelectric conversion element, and a method for manufacturing a thermoelectric conversion element. Furthermore, as other aspects, the invention provides a dispersing agent of a nanocarbon material and a composition containing the dispersing agent and a nanocarbon material. Hereinafter, these will be explained.

The thermoelectric conversion material of the invention contains (a) a nanocarbon material and (b) a dispersing agent of the nanocarbon material as essential components and other components as necessary.

[(a) Nanocarbon Material]

As the nanocarbon material that is used in the invention, a nanometer-sized carbon material having electroconductive properties may be used.

Examples of the nanocarbon material include nanometer-sized electroconductive materials formed of carbon atoms that are chemically bonded together by means of a carbon-carbon bond constituted of a sp² hybrid orbit of a carbon atom. Specific examples thereof include fullerenes (including endohedral metallofullerenes and onion-shaped fullerenes), carbon nanotubes (including peapods (hereinafter, a carbon nanotube will also be referred to as CNT)), carbon nanohoms having a form of a carbon nanotube with one side closed, carbon nanofibers, carbon nanowalls, carbon nanofilaments, carbon nanocoils, vapor grown carbon fibers (VGCF), graphite, graphene, carbon nanoparticles, and cup-shaped nanocarbon substances which are carbon nanotubes having a hole in a head part. In addition, as the nanocarbon material, it is also possible to use a variety of carbon blacks which have a graphite-type crystal structure and exhibit electroconductive properties. Examples thereof include Ketjenblack and acetylene black, and specific examples thereof include carbon black such as “VULCAN” (trade name, Cabot Corporation).

The nanocarbon material can be manufactured using a manufacturing method of the related art. Specific examples thereof include catalytic hydrogen reduction of carbon dioxide, an arc discharge method, a laser vaporization method, a CVD method, a vapor-phase epitaxial method, a vapor-phase fluid method, a HiPco method in which carbon monoxide is reacted together with an iron catalyst at a high temperature and a high pressure so as to be grown, and an oil furnace method. The nanocarbon material manufactured in the above-described manner can be used as it is or can be used after being purified by means of cleaning, centrifugal separation, filtration, oxidization, chromatography, and the like. Furthermore, the nanocarbon material can also be used after being crushed using a ball-type kneading apparatus such as a ball mill, an oscillatory mill, a sand mill, or a roll mill or after being cut into short pieces by means of a chemical or physical treatment.

The size of the nanocarbon material that is used in the invention is not particularly limited as long as the size is on a nanometer scale. In case in which the nanocarbon material is a carbon nanotube, a carbon nanohorn, a carbon nanofiber, a carbon nanofilament, a carbon nanocoil, a vapor grown carbon fiber (VGCF), a cup-shaped nanocarbon substance, or the like, the average length is preferably 0.01 μm to 1,000 μm and more preferably 0.1 μm to 100 μm from the viewpoint of easy manufacturing, film-forming properties, electroconductive properties, and the like. In addition, the average diameter thereof is preferably 0.4 nm to 100 nm (more preferably 50 nm or smaller and still more preferably 15 nm or smaller) from the viewpoint of durability, transparency, film-forming properties, electroconductive properties, and the like.

The nanocarbon material that is used in the invention is preferably a carbon nanotube, a carbon nanofiber, a fullerene, graphite, graphene, or carbon nanoparticles and, from the viewpoint of electroconductive properties and improvement of dispersibility in a solvent, a carbon nanotube is particularly preferred.

Hereinafter, a carbon nanotube will be explained. As CNTs, there are a single-layer CNT that is a carbon film (graphene sheet) wound in a cylindrical shape, a bilayer CNT that is made of two graphene sheets wound in a concentric shape, and a multilayer CNT that is made of a plurality of graphene sheets wound in a concentric shape. In the invention, each of a single-layer CNT, a bilayer CNT, and a multilayer CNT may be used singly, or two or more kinds thereof may be used in combination. Particularly, a single-layer CNT and a bilayer CNT which have excellent properties in terms of electroconductive properties and semiconductor characteristics are preferably used, and a single-layer CNT is more preferably used.

In the case of a single-layer CNT, the symmetry of a spiral structure based on the orientation of hexagons of graphene in a graphene sheet is referred to as the axial chirality, and the two-dimensional lattice vector of a 6-membered ring from a standard point on graphene is referred to as the chiral vector. (n, m) obtained by indexing the chiral vector is referred to as the chiral index, and graphene is classified into metallic graphene and semiconductor graphene using this chiral index. Specifically, graphene having (n−m) that is a multiple of 3 exhibits metallic properties, and graphene having (n−m) that is not a multiple of 3 exhibits semiconductor properties.

A single-layer CNT that is used in the invention may be a semiconductor CNT or a metallic CNT, and both a semiconductor CNT and a metallic CNT may be jointly used. In addition, CNT may include a metal, and CNT including a molecule of a fullerene or the like (particularly, CNT including fullerene is referred to as a peapod) may also be used.

CNT can be manufactured using an arc discharge method, a chemical vapor deposition method (hereinafter, referred to as a CVD method), a laser application method, or the like. CNT that is used in the invention may be obtained using any method, but CNT obtained using an arc discharge method or a CVD method is preferred.

During the manufacturing of CNT, there are cases in which a fullerene or graphite and amorphous carbon are generated at the same time as byproducts. CNT may be purified in order to remove these byproducts. A method for purifying CNT is not particularly limited, and, in addition to the above-described purification method, an acid treatment using nitric acid, sulfuric acid, or the like and an ultrasonic treatment are effective for removing impurities. It is more preferable to separate and remove impurities using a filter together with the above-described purification method from the viewpoint of improving the purity.

After purification, the obtained CNT may be used as it is. In addition, since CNT is generally generated in a string shape, CNT may be used after being cut into a desired length depending on the applications. CNT can be cut into a short fiber shape by means of an acid treatment using nitric acid, sulfuric acid, or the like, an ultrasonic treatment, or a frost shattering method. In addition, it is also preferable to separate impurities using a filter together with the above-described cutting method from the viewpoint of improving the purity.

In the invention, not only cut CNT but also CNT produced in a short fiber shape in advance can be used in the same manner. The above-described short fiber-shaped CNT is obtained in a shape in which CNT is aligned in a direction vertical to the substrate surface by, for example, forming a catalyst metal such as iron or cobalt on a substrate and growing CNT in a vapor phase on the surface by thermally decomposing a carbon compound at 700° C. to 900° C. using a CVD method. The short fiber-shaped CNT produced in the above-described manner can be pulled out from the substrate using a method such as peeling. In addition, the short fiber-shaped CNT can be obtained by supporting a catalyst metal on a porous support such as porous silicon or an anodized film of alumina and growing CNT on the surface thereof using a CVD method. It is also possible to produce an aligned short fiber-shaped CNT using a method in which a molecule such as iron phthalocyanine including a catalyst metal in the molecule is used as a raw material and CVD is performed in an argon/hydrogen gas flow, thereby producing CNT on the substrate. Furthermore, it is also possible to obtain a short fiber-shaped CNT aligned on a SiC crystal surface using an epitaxial growth method.

The content of the nanocarbon material in the thermoelectric conversion material is preferably 5% by mass to 80% by mass, more preferably 5% by mass to 70% by mass, and particularly preferably 5% by mass to 50% by mass of the total solid content of the thermoelectric conversion material, that is, in a thermoelectric conversion layer from the viewpoint of the thermoelectric conversion performance.

Only one nanocarbon material may be used singly, or two or more kinds thereof may be used in combination.

[(b) Dispersing Agent of Nanocarbon Material]

The dispersing agent of the invention is a compound having an anchoring group to the nanocarbon material and a steric repulsive group and having a decomposable group between the anchoring group and the steric repulsive group. The decomposable group is preferably a group that decomposes due to the action of heat or an acid.

The dispersing agent increases the dispersibility of the nanocarbon material in the thermoelectric conversion material and, furthermore, makes a thermoelectric conversion element comprising a thermoelectric conversion layer formed of the above-described material exhibit excellent thermoelectric conversion performance. The mechanism thereof is not yet clear but is assumed as described below.

That is, when the nanocarbon material and the dispersing agent of the invention are blended with a solvent or a resin, the dispersing agent is anchored to the nanocarbon material due to the action of the anchoring group. The nanocarbon material particles to which the dispersing agent is anchored are repulsed from each other due to the action of the steric repulsive group in the dispersing agent and thus become incapable of easily aggregating. As a result, the dispersibility of the nanocarbon material becomes favorable. When the dispersing agent is used together with the nanocarbon material in the thermoelectric conversion material, it is possible to obtain a thermoelectric conversion material having excellent dispersibility of the nanocarbon material. The above-described thermoelectric conversion material is extremely suitable for forming a thermoelectric conversion layer using a coating method.

In addition, in order to improve the thermoelectric conversion performance, it is desirable to allow charges to smoothly migrate and diffuse between the nanocarbon material particles in the thermoelectric conversion layer. The dispersing agent of the invention has a decomposable group between the anchoring group and the steric repulsive group, and the decomposable group is decomposed by heat or an acid. After or while the thermoelectric conversion layer is formed by applying the thermoelectric conversion material, a thermal or acid treatment is carried out on the thermoelectric conversion layer so as to decompose the decomposable group, whereby the anchoring group is left on the nanocarbon material, and the decomposable group and the steric repulsive group are desorbed. When the repulsive action of the steric repulsive group disappears, the nanocarbon material particles easily come into contact with each other, and it becomes easy for a carrier path to be built between the nanocarbon material particles. Since the carrier path promotes the migration and diffusion of charges between the nanocarbon material particles, electroconductive properties and thermoelectromotive force improve. As a result, the thermoelectric conversion performance improves.

The dispersing agent of the invention is preferably a polymer compound including a repeating unit represented by General Formula (1A) below and a repeating unit represented by General Formula (1B) below:

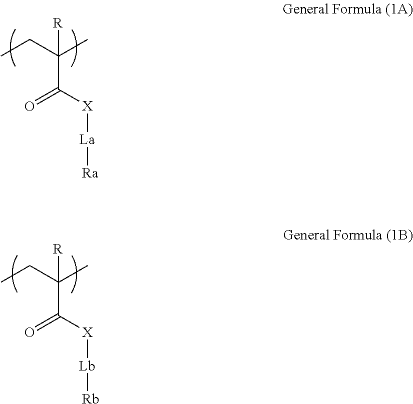

In General Formula (1A), Ra represents an aromatic group, an alicyclic group, an alkyl group, a hydroxyl group, a thiol group, an amino group, an ammonium group, or a carboxyl group. La represents a divalent group having an acetal structure, a tertiary alkyl ester structure, or a peroxide structure. R represents a hydrogen atom or an alkyl group having 1 to 4 carbon atoms. X represents an oxygen atom or —NH—.

In General Formula (1B), Rb represents a monovalent group derived from a polyalkylene oxide compound, a poly(meth)acrylate compound, a polysiloxane compound, a polyacrylonitrile compound, or a polystyrene compound, a monovalent group obtained by combining the above-described compounds, or an alkyl group having 5 or more carbon atoms. Lb represents a single bond or a divalent linking group. R and X are identical to those in General Formula (1A).

Ra in General Formula (1A) corresponds to the anchoring group to the nanocarbon material. Ra is preferably an aromatic group.

A ring constituting the aromatic group as Ra may be an aromatic hydrocarbon ring or an aromatic hetero ring, and examples of a heteroatom in the hetero ring include a nitrogen atom, a sulfur atom, an oxygen atom, and a selenium atom. In addition, the ring may be a single ring or a fused ring, and is preferably a 5-membered ring, a 6-membered ring, or a fused ring thereof and more preferably a 6-membered ring or a fused ring thereof. Specific examples thereof include a benzene ring, a naphthalene ring, an anthracene ring, a pyrene ring, a chrysene ring, a tetracene ring, a tetraphene ring, a triphenylene ring, an indole ring, an isoquinoline ring, a quinoline ring, a chromene ring, an acridine ring, a xanthene ring, a carbazole ring, a porphyrin ring, a chlorine ring, and a corrin ring. Ra is preferably an aromatic hydrocarbon ring, more preferably a benzene ring or a fused ring of a benzene ring, and still more preferably a benzene ring or a fused ring of 2 to 4 benzene rings that are fused together.

An alicyclic compound constituting the alicyclic group as Ra may include a heteroatom, and examples of the heteroatom include a nitrogen atom, a sulfur atom, an oxygen atom, and a selenium atom. In addition, the alicyclic compound may be a single ring or a fused ring, and is preferably a 5-membered ring, a 6-membered ring, or a fused ring thereof and more preferably a 6-membered ring or a fused ring thereof. In addition, the alicyclic compound may be a saturated ring or an unsaturated ring. Specific examples thereof include a cyclohexane ring, a cyclopropane ring, an adamantyl ring, and a tetrahydronaphthalene ring. The alicyclic compound is preferably a hydrocarbon ring which is a hydrocarbon ring of a 6-membered ring or a fused ring thereof.

The alkyl group as Ra may have any of a straight shape, a branched shape, and a cyclic shape and is preferably a straight alkyl group. The number of carbon atoms in the alkyl group is preferably 1 to 30 and more preferably 5 to 20.

Examples of the amino group as Ra include an alkylamino group and an arylamino group, and specific examples thereof include a dimethylamino group, a diethylamino group, a dibutylamino group, a dipropylamino group, a methylamino group, an ethylamino group, a butylamino group, a propylamino group, and an amino group. Among these, an alkylamino group is preferred. The number of carbon atoms in each of alkyl groups in the alkylamino group is preferably 1 to 7 and more preferably 1 to 4.

Examples of the ammonium group as Ra include an alkylammonium group and an arylammonium group. Specific examples thereof include a trimethylammonium group, a triethylammonium group, a tripropylammonium group, and a tributylammonium group. Among these, an alkylammonium group is preferred. The number of carbon atoms in each of alkyl groups in the alkylammonium group is preferably 1 to 7 and more preferably 1 to 4.

Examples of the thiol group as Ra include a thioalkyl group.

The respective groups as Ra may further have a substituent.

La in General Formula (1A) corresponds to the decomposable group. The decomposable group is decomposed by the action of heat or an acid.

La has at least one structure selected from an acetal structure, a tertiary alkyl ester structure, and a peroxide structure (—O—O—) and may have a plurality of these structures.

The acetal structure is preferably a structure represented by —R¹O—CH(OR²)R³—. Here, each of R¹ and R³ independently represents an alkylene group, and R² represents an alkyl group. The number of carbon atoms in each of the alkylene group and the alkyl group is preferably 1 or 2.

The tertiary alkyl ester structure is preferably a structure represented by —R⁴—C(R⁵)(R⁶)—O—C(═O)—. Here, R⁴ represents an alkylene group, and each of R⁵ and R⁶ independently represents an alkyl group. The number of carbon atoms in each of the alkylene group and the alkyl group is preferably 1 or 2.

La is preferably a divalent group having any one of the acetal structure and the tertiary alkyl ester structure.

The alkyl group as R may have any of a straight shape, a branched shape, and a cyclic shape and is preferably a straight alkyl group. The alkyl group may be substituted, and a substituent is preferably a halogen atom, an oxygen atom, or a sulfur atom. The number of carbon atoms in the alkyl group is preferably 1 to 3 and more preferably 1 or 2.

R is preferably an alkyl group having 1 or 2 carbon atoms and more preferably a methyl group.

X is preferably an oxygen atom.

Specific examples of the repeating unit represented by General Formula (1A) (hereinafter, also referred to as repeating unit (1A)) will be illustrated below, but the invention is not limited thereto:

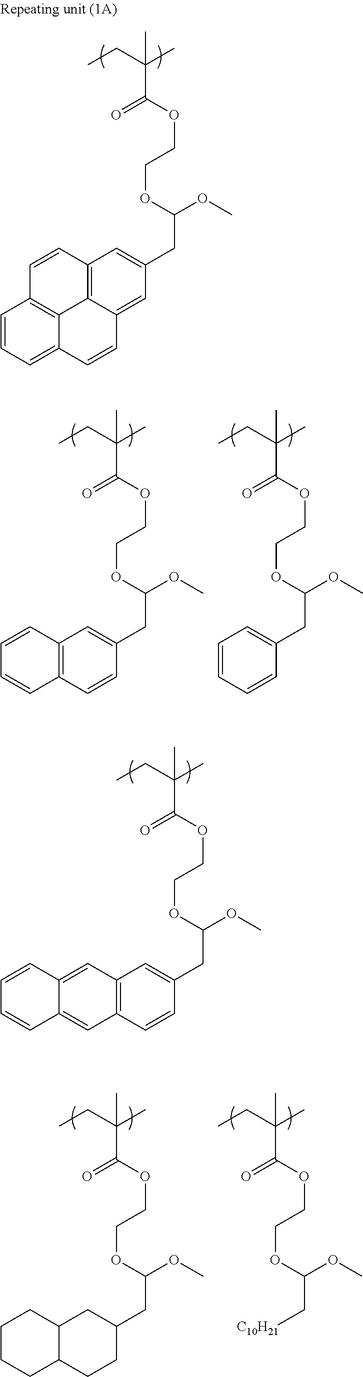

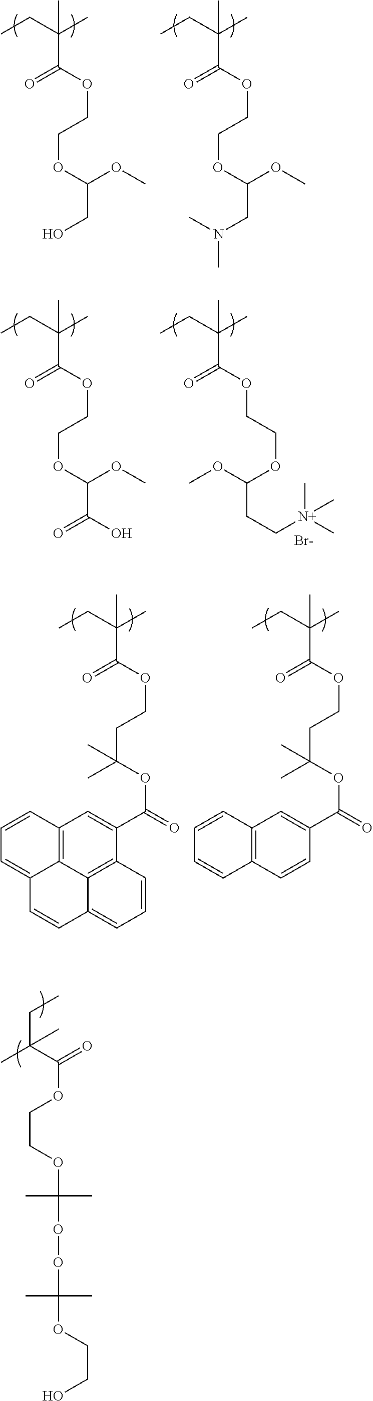

Rb in General Formula (1B) corresponds to the steric repulsive group.

The alkyl group as Rb may have any of a straight shape, a branched shape, and a cyclic shape and is preferably a straight alkyl group. The number of carbon atoms in the alkyl group is 5 or more, preferably 5 to 20, and more preferably 6 to 20. The alkyl group may have a substituent.

In case in which Rb is a monovalent group derived from a polyalkylene oxide compound, a poly(meth)acrylate compound, a polysiloxane compound, a polyacrylonitrile compound, or a polystyrene compound, Rb is preferably bonded with Lb at the terminal group of a polymer main chain thereof.

The repeating number of individual monomers constituting the polyalkylene oxide compound, the poly(meth)acrylate compound, the polysiloxane compound, the polyacrylonitrile compound, and the polystyrene compound is preferably 30 to 5,000 and more preferably 30 to 1,000.

The polyalkylene oxide compound, the poly(meth)acrylate compound, the polysiloxane compound, the polyacrylonitrile compound, or the polystyrene compound may have a substituent.

Specific examples of the polyalkylene oxide compound include polyethylene oxide, polypropylene oxide, and polybutylene oxide, and polyethylene oxide is preferred.

Specific examples of the poly(meth)acrylate compound include poly(methyl methacrylate), poly(isobutyl methacrylate), poly(ethyl methacrylate), poly(propyl methacrylate), poly(isopropyl methacrylate), poly(isobornyl methacrylate), poly(2-ethylhexyl methacrylate), poly(cyclohexyl methacrylate), poly(stearyl methacrylate), poly(tetrahydrofurfuryl methacrylate), poly(tridecyl methacrylate), poly(benzyl methacrylate), and poly(lauryl methacrylate), and poly(methyl methacrylate) and poly(isobutyl methacrylate) are preferred.

Specific examples of the polysiloxane compound include dimethylpolysiloxane and diethylpolysiloxane, and dimethylpolysiloxane is preferred.

Specific examples of the polyacrylonitrile compound include polyacrylonitrile. Specific examples of the polystyrene compound include polystyrene and poly(4-methoxystyrene), and polystyrene is preferred.

Rb is preferably a monovalent group derived from the poly(meth)acrylate compound or the polystyrene compound and more preferably a monovalent group derived from the poly(meth)acrylate compound.

Examples of the divalent linking group as Lb include an alkylene group, —O—, —CO—, —COO—, —CONH—, —S—, —S(═O)—, and divalent groups obtained by combining the above-described divalent linking groups. Here, each of R¹¹ and R¹² independently represents a hydrogen atom or an alkyl group, and the number of carbon atoms in the alkyl group is preferably 1 or 2. The alkylene group may have a substituent, and examples of the substituent include a hydroxyl group, a halogen atom, an alkyl group, an alkoxy group, an amino group, an ammonium group, and an ester group. The number of carbon atoms in the alkylene group is preferably 1 to 7. In addition, the number of carbon atoms in Lb is preferably 1 to 20 and more preferably 1 to 10.

Lb is preferably a divalent group obtained by combining an alkylene group, —O—, —CO—, and —S—. In this case, Lb is more preferably bonded with X through the alkylene group and bonded with Rb through —S—.

R and X in General Formula (1B) are identical to those in General Formula (1A), and preferred ranges thereof are also the same.

Specific examples of the repeating unit represented by General Formula (1B) (hereinafter, also referred to as repeating unit (1B)) will be illustrated below, but the invention is not limited thereto. Meanwhile, in the following specific examples, each of n and m represents an integer of 1 or greater:

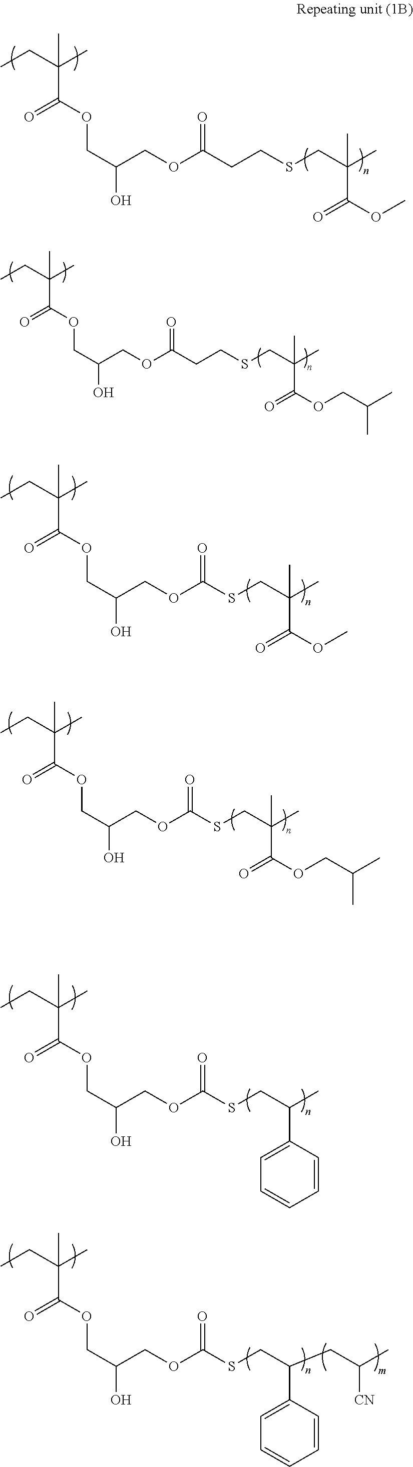

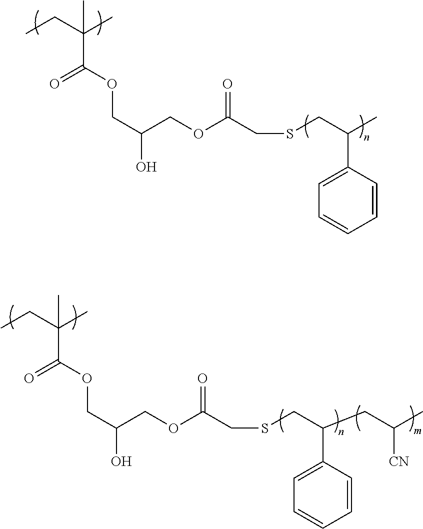

Specific examples of a combination of the repeating unit represented by General Formula (1A) and the repeating unit represented by General Formula (1B) will be illustrated below, but the invention is not limited thereto. Meanwhile, in the following specific examples, each of n and m represents an integer of 1 or greater:

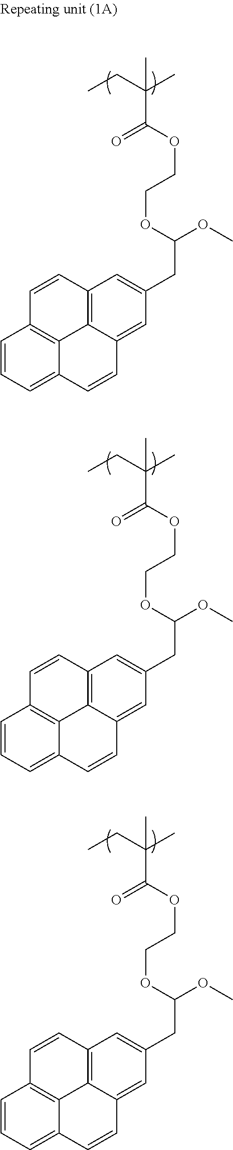

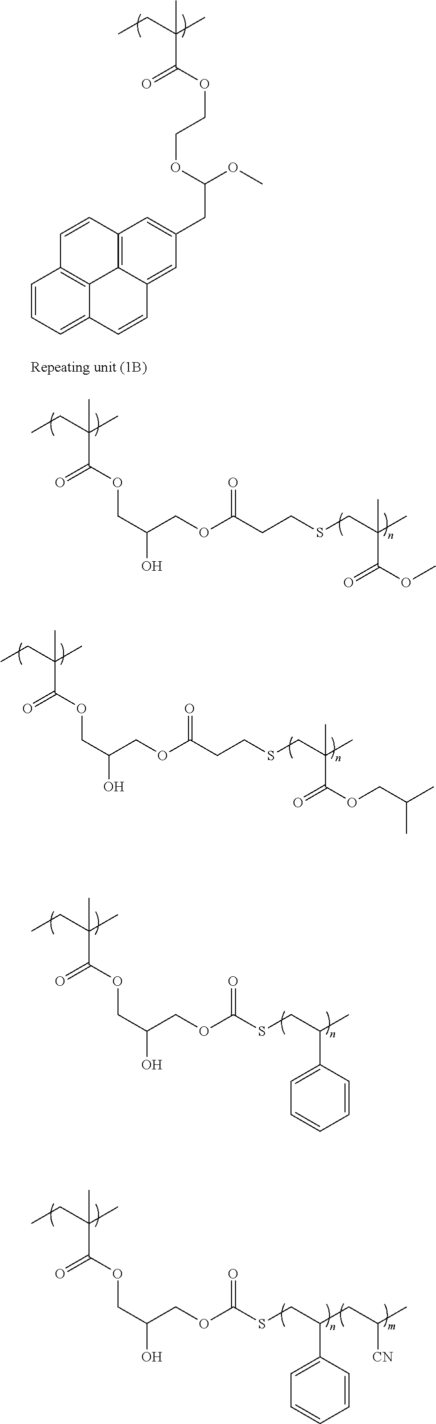

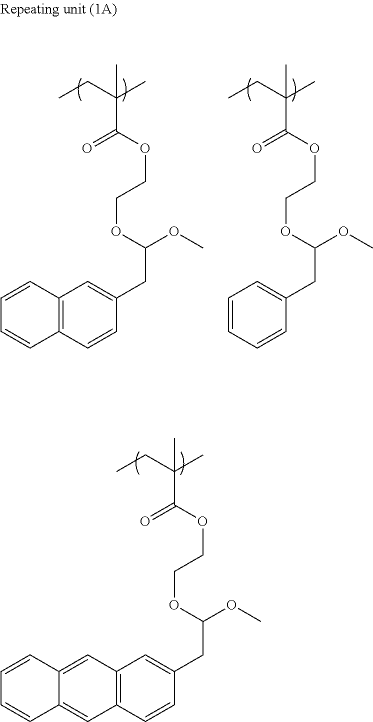

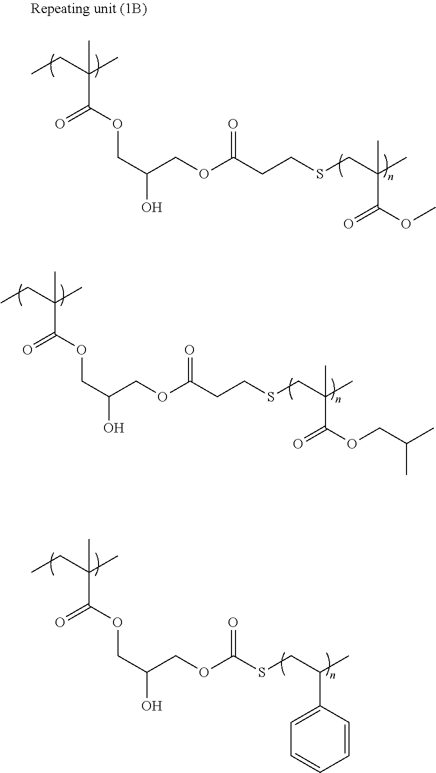

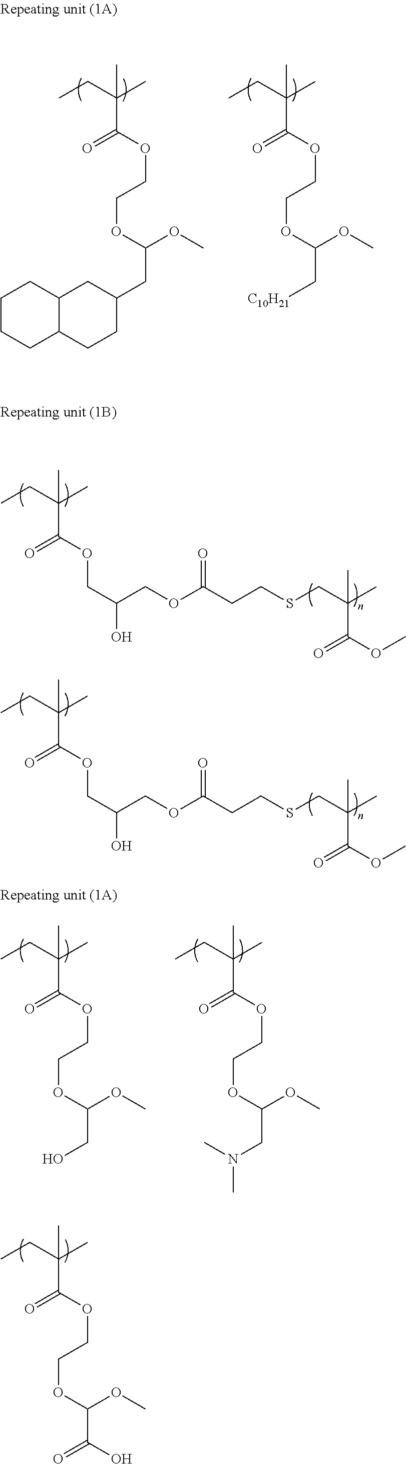

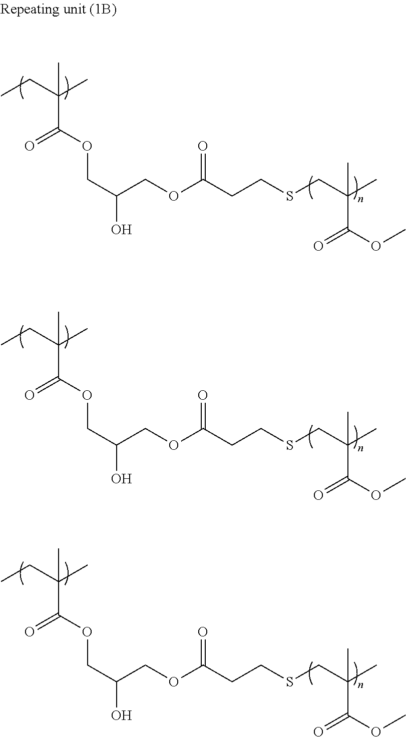

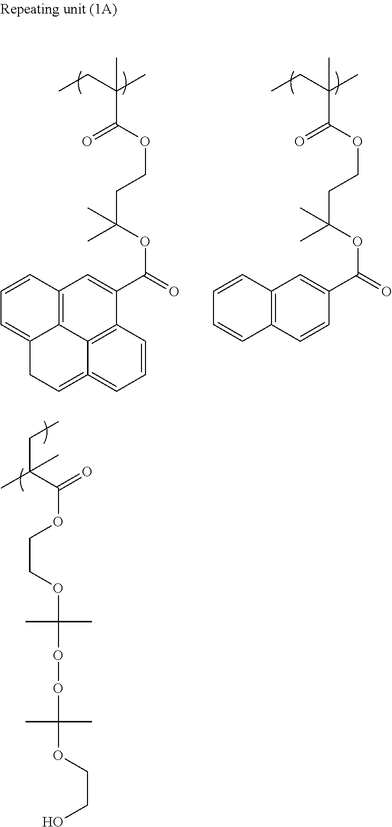

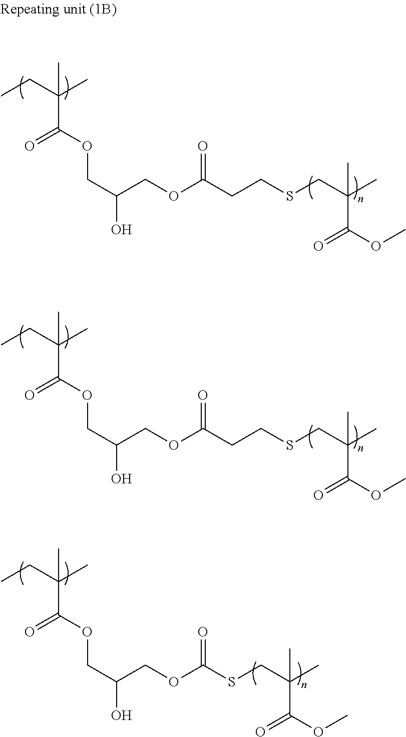

The dispersing agent of the invention may include a repeating unit other than the repeating units (1A) and (1B), and the repeating unit is preferably a copolymer consisting of the repeating units (1A) and (1B).

A copolymer including the repeating units (1A) and (1B) may be any one of a graft copolymer, a block copolymer, a random copolymer and an alternate copolymer. A graft copolymer is preferred since it is easy to uniformly dispose the steric repulsive group at a high density on the surface of a dispersion and to synthesize the graft copolymer. The above-described copolymer can be synthesized using a method in which a monomer and a macromonomer are copolymerized together, thereby obtaining a graft copolymer, a method in which a monomer and a monomer having a polymerization initiation site are copolymerized together and thus are polymerized from a polymer chain, a method in which a polymer reaction is performed between a polymer having a reactive group and another polymer, thereby synthesizing a graft copolymer, or the like. Among these, from the viewpoint of the introduction ratio of a graft chain and the easy control of the graft chain length and the like, the method in which a monomer and a macromonomer are copolymerized together, thereby obtaining a graft copolymer is preferred.

The graft copolymer preferably has a main chain formed by the copolymerization of the repeating unit (1A) and the repeating unit (1B) and has the steric repulsive group in the repeating unit (1B) as a side chain. In this case, the repeating unit (1B) site in the copolymer is preferably formed of a macromonomer. That is, the graft copolymer is preferably synthesized by copolymerizing a macromonomer capable of forming the repeating unit (1B) and a monomer capable of forming the repeating unit (1A).

Regarding the mole-based compositional ratio between the repeating units (1A) and (1B) in the copolymer including the repeating units (1A) and (1B), the repeating unit (1A): the repeating unit (1B) is preferably 20 to 90:80 to 10 and more preferably 40 to 80:60 to 20.

In addition, the weight-average molecular weight of the copolymer is preferably 1,000 to 800,000 and more preferably 10,000 to 300,000. Meanwhile, the weight-average molecular weight can be measured using gel permeation chromatography (GPC). For example, it is possible to calculate the weight-average molecular weight in terms of polystyrene using a high-speed GPC apparatus (for example, HLC-8220GPC (manufactured by Tosoh Corporation)) after dissolving a polymer compound in tetrahydrofuran (THF).

In addition, the dispersing agent of the invention is also preferably a compound represented by General Formula (2) below:

RaₙLₘRb General Formula (2)

In General Formula (2), Ra is identical to Ra in General Formula (1A), and a preferred range thereof is also the same. Rb is identical to Rb in General Formula (1B), and a preferred range thereof is also the same. L represents a (n+m)-valent organic group having an acetal structure, a tertiary alkyl ester structure, or a peroxide structure. Each of n and m independently represents an integer of 1 to 4.

In General Formula (2), Ra corresponds to the anchoring group to the nanocarbon material, L corresponds to the decomposable group, and Rb corresponds to the steric repulsive group, respectively.

L in General Formula (2) has at least one structure selected from an acetal structure, a tertiary alkyl ester structure, and a peroxide structure (—O—O—) and may have a plurality of these structures. In addition, L may have a different structure. Examples of the different structure include an alkylene group, —O—, —CO—, —O—CO—, and —S—. The alkylene group may have a substituent, and examples of the substituent include a hydroxyl group. The number of carbon atoms in the alkylene group is preferably 1 to 20 and more preferably 1 to 10.

The acetal structure is preferably a structure represented by —O—CH₂—O—.

L is preferably a divalent group having the acetal structure and more preferably a divalent group obtained by combining the acetal structure, an alkylene group, and —O—CO— or a divalent group obtained by combining the acetal structure and an alkylene group.

In General Formula (2) each of n and m is independently preferably an integer of 1 or 2 and more preferably 1.

Specific examples of the compound represented by General Formula (2) will be illustrated below, but the invention is not limited thereto. Meanwhile, in the following specific examples, n represents an integer of 1 or greater:

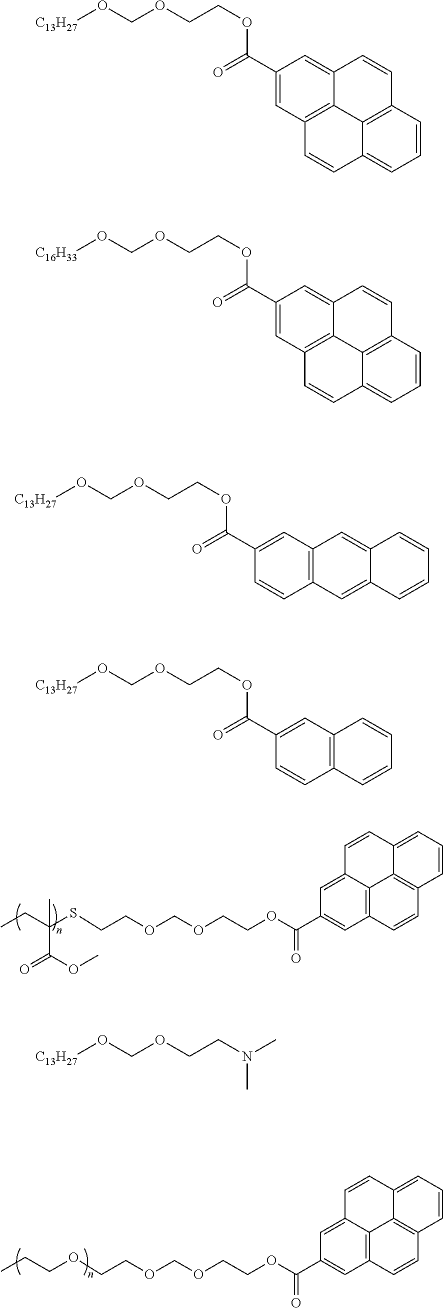

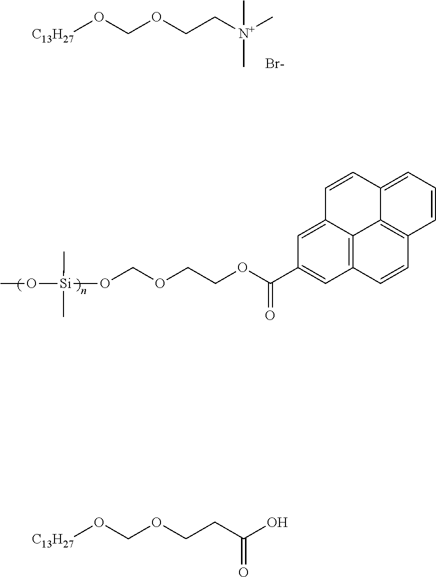

The molecular weight of the compound represented by General Formula (2) is preferably 100 to 10,000.

The compound represented by General Formula (2) can be synthesized using a method in which an L part having 2 or more reactive groups and an Ra part and an Rb part which have a functional group that reacts with the reactive group of L are reacted with each other, a method in which an Ra-L part having 2 or more reactive groups and an Rb part having a functional group that reacts with the reactive group are reacted with each other, a method in which an Rb-L part having 2 or more reactive groups and Ra having a functional group that reacts with the reactive group are reacted with each other, or the like.

The dispersing agent of the invention is more preferably a polymer compound including the repeating unit represented by General Formula (1A) and the repeating unit represented by General Formula (1B).

The percentage content of the dispersing agent in the thermoelectric conversion material is preferably 5 parts by mass to 100 parts by mass and more preferably 10 parts by mass to 80 parts by mass, relative to 100 parts by mass of the nanocarbon material, from the viewpoint of the thermoelectric conversion performance.

In the thermoelectric conversion material of the invention, the dispersing agent may be used singly, or two or more kinds thereof may be used in combination.

[(c) Dispersion Medium]

The thermoelectric conversion material of the invention preferably contains a dispersion medium.

The dispersion medium may be any dispersion medium capable of dispersing the nanocarbon material, and water, an organic solvent, and a solvent mixture thereof can be used. The dispersion medium is preferably an organic solvent, and aliphatic halogen-based solvents such as an alcohol and chloroform, aprotic polar solvents such as N,N-dimethylformamide (DMF), N-methylpyrrolidone (NMP), and dimethyl sulfoxide (DMSO), aromatic solvents such as chlorobenzene, dichlorobenzene, benzene, toluene, xylene, mesitylene, tetralin, tetramethyl benzene, and pyridine, ketone-based solvents such as cyclohexanone, acetone, and methyl ethyl ketone, ether-based solvents such as diethyl ether, tetrahydrofuran (THF), t-butyl methyl ether, dimethoxyethane, and diglyme, and the like are preferred, and aliphatic halogen-based solvents such as chloroform, aprotic polar solvents such as DMF and NMP, aromatic solvents such as dichlorobenzene, xylene, tetralin, and tetramethyl benzene, ether-based solvents such as THF, and the like are more preferred.

In the thermoelectric conversion material of the invention, the dispersion medium can be used singly, or two or more kinds of dispersion media can be used in combination.

In addition, the dispersion medium is preferably degassed in advance. The dissolved oxygen level in the dispersion medium is preferably set to 10 ppm or less. Examples of a degassing method include a method in which ultrasonic waves are radiated at a reduced pressure and a method in which an inert gas such as argon is bubbled.

Furthermore, the dispersion medium is preferably dehydrated in advance. The amount of moisture in the dispersion medium is preferably set to 1,000 ppm or less and more preferably set to 100 ppm or less. As a method for dehydrating the dispersion medium, it is possible to use a well-known method such as the use of a molecular sieve or distillation.

The amount of the dispersion medium in the thermoelectric conversion material is preferably 25% by mass to 99.99% by mass, more preferably 30% by mass to 99.95% by mass, and still more preferably 30% by mass to 99.9% by mass, relative to the total amount of the thermoelectric conversion material.

[Other Components]

The thermoelectric conversion material of the invention may contain other components in addition to the nanocarbon material, the dispersing agent, and the dispersion medium.

Examples of other components include polymer compounds other than the dispersing agent (hereinafter, other polymer compounds), an oxidation inhibitor, a light-fast stabilizer, a heat-resistant stabilizer, and a plasticizer.

Examples of the other polymer compounds include conjugated polymers and non-conjugated polymers.

Examples of the oxidation inhibitor include IRGANOX 1010 (trade name, manufactured by Ciba-Geigy Japan Limited), SUMILIZER GA-80 (trade name, manufactured by Sumitomo Chemical Co., Ltd.), SUMILIZER GS (trade name, manufactured by Sumitomo Chemical Co., Ltd.), and SUMILIZER GM (trade name, manufactured by Sumitomo Chemical Co., Ltd.).

Examples of the light-fast stabilizer include TINUVIN 234 (trade name, manufactured by BASF), CHIMASSORB 81 (trade name, manufactured by BASF), and CYASORB UV-3853 (trade name, manufactured by Sun Chemical Company LTD.).

Examples of the heat-resistant stabilizer include IRGANOX 1726 (trade name, manufactured by BASF). Examples of the plasticizer include ADEKACIZER RS (trade name, manufactured by Adeka Corp.).

The percentage content of the other components is preferably 5% by mass or less and more preferably 0% by mass to 2% by mass, relative to the total solid content of the thermoelectric conversion material.

[Preparation of Thermoelectric Conversion Material]

The thermoelectric conversion material of the invention can be prepared by mixing the respective components described above. Preferably, the thermoelectric conversion material is prepared by mixing the nanocarbon material, the dispersing agent, and the other components as desired into the dispersion medium, and dispersing the nanocarbon material.

There are no particular limitations on the method for preparing the thermoelectric conversion material, and the method can be carried out at a normal temperature and a normal pressure using a conventional mixing apparatus or the like. For example, the thermoelectric conversion material may be produced by stirring, shaking or kneading various components in a solvent, and thereby dissolving or dispersing the components. In order to promote dissolution or dispersion, an ultrasonication treatment may be carried out.

Furthermore, the dispersibility of the nanocarbon material can be increased by heating the solvent to a temperature that is higher than or equal to room temperature and lower than or equal to the boiling point in the dispersing step, by extending the dispersion time, or by increasing the application intensity of stirring, percolation, kneading, ultrasonication or the like.

[Thermoelectric Conversion Element]

A thermoelectric conversion element of the invention has, on a base material, a first electrode, a thermoelectric conversion layer, and a second electrode, and the thermoelectric conversion layer is formed using the thermoelectric conversion material of the invention.

Since the thermoelectric conversion element functions by maintaining a temperature difference in the thickness direction or the surface direction of the thermoelectric conversion layer, the thermoelectric conversion layer needs to have a certain degree of thickness. Therefore, in case in which the thermoelectric conversion layer is formed using a coating method, the thermoelectric conversion material to be applied needs to have favorable coatability and film-forming properties. The thermoelectric conversion material of the invention has favorable dispersibility of the nanocarbon material and is excellent in terms of coatability or film-forming properties, and is thus suitable for being molded and processed into the thermoelectric conversion layer.

As long as the thermoelectric conversion element of the invention has, on a base material, a first electrode, a thermoelectric conversion layer, and a second electrode, and at least one surface of the thermoelectric conversion layer is disposed so as to be in contact with the first electrode and the second electrode, there are no particular limitations on other constitutions such as the positional relationship between the first electrode, the second electrode, and the thermoelectric conversion layer. For example, the thermoelectric conversion element may have an embodiment in which the thermoelectric conversion layer is sandwiched between the first electrode and the second electrode, that is, an embodiment in which the first electrode, the thermoelectric conversion layer, and the second electrode are provided on the base material in this order. In addition, the thermoelectric conversion element may have an embodiment in which the first electrode and the second electrode are disposed so as to be in contact with one surface of the thermoelectric conversion layer, that is, an embodiment in which the first electrode and the second electrode are formed apart from each other on the same base material and the thermoelectric conversion layer is laminated on both electrodes.

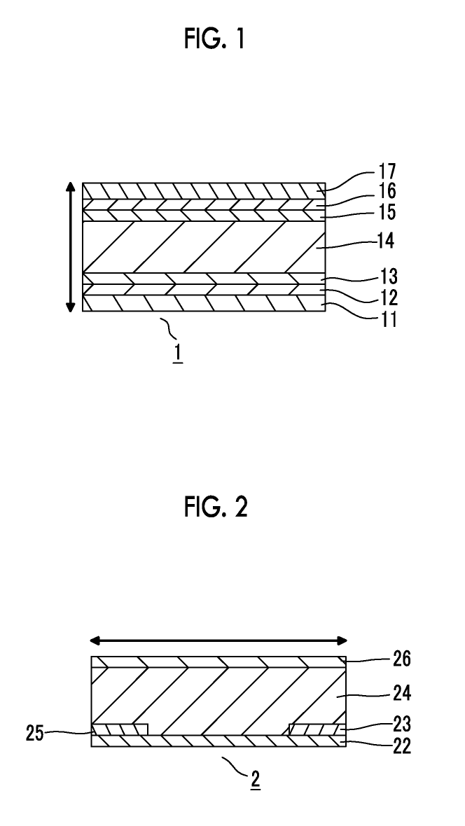

Examples of the structure of the thermoelectric conversion element of the invention include the structures of the element illustrated in FIGS. 1 and 2. In FIGS. 1 and 2, the arrows indicate the directions of temperature differences during the use of the thermoelectric conversion element.

A thermoelectric conversion element 1 illustrated in FIG. 1 comprises a pair of electrodes including a first electrode 13 and a second electrode 15 and a thermoelectric conversion layer 14 formed of the thermoelectric conversion material of the invention between the electrodes 13 and 15 on a first base material 12. A second base material 16 is disposed on the other surface of the second electrode 15, and metal plates 11 and 17 are disposed opposite to each other on the outside of the first base material 12 and the second base material 16.

In a thermoelectric conversion element 2 illustrated in FIG. 2, a first electrode 23 and a second electrode 25 are disposed on a first base material 22, and a thermoelectric conversion layer 24 formed of the thermoelectric conversion material of the invention is provided thereon.

From the viewpoint of protecting the thermoelectric conversion layer, the surface of the thermoelectric conversion layer is preferably covered with the electrode or the base material. For example, as illustrated in FIG. 1, it is preferable that one surface of the thermoelectric conversion layer 14 is covered with the first base material 12 through the first electrode 13 and the other surface is covered with the second base material 16 through the second electrode 15. In this case, the second electrode 15 may be exposed to air as an outermost surface without providing the second base material 16 on the outside of the second electrode 15. In addition, as illustrated in FIG. 2, it is preferable that one surface of the thermoelectric conversion layer 24 is covered with the first electrode 23, the second electrode 25, and the first base material 22 and the other surface is also covered with a second base material 26.

In addition, on the surface (a surface that is pressure-bonded to the thermoelectric conversion layer) of a base material that is used for the thermoelectric conversion element, the electrodes are preferably formed in advance. It is preferable that the base material or the electrodes and the thermoelectric conversion layer are pressure-bonded to each other by heating the members to approximately 100° C. to 200° C. from the viewpoint of improving the adhesiveness.

As the base material (the first base material 12 and the second base material 16 in the thermoelectric conversion element 1) in the thermoelectric conversion element of the invention, it is possible to use a base material such as glass, transparent ceramic, metal, or a plastic film. In the thermoelectric conversion element of the invention, the base material preferably has flexibility and, specifically, preferably has a flexibility at which the endurance number of cycles in a bend test (MIT) by the measurement method regulated by ASTM D2176 is 10,000 cycles or more. The base material having the above-described flexibility is preferably a plastic film, and specific examples thereof include polyester films such as films of polyethylene terephthalate, polyethylene isophthalate, polyethylene naphthalate, polybutylene terephthalate, poly(1,4-cyclohexylene dimethylene terephthalate), polyethylene-2,6-phthalene dicarboxylate, and a polyester film of bisphenol A with iso- and terephthalic acid; polycycloolefine films such as a ZEONOR film (trade name, manufactured by Zeon Corp.), an ARTON film (trade name, manufactured by JSR Corp.), and SUMILITE FS1700 (trade name, manufactured by Sumitomo Bakelite Co., Ltd.); polyimide films such as KAPTON (trade name, manufactured by Du Pont-Toray Co., Ltd.), APICAL (trade name, manufactured by Kaneka Corp.), UPILEX (trade name, manufactured by Ube Industries, Ltd.), and POMIRAN (trade name, manufactured by Arakawa Chemical Industries, Ltd.); polycarbonate films such as PURE-ACE (trade name, manufactured by TEIJIN LIMITED.) and ELMECH (trade name, manufactured by Kaneka Corp.); polyether ether ketone films such as SUMILITE FS1100 (trade name, manufactured by Sumitomo Bakelite Co., Ltd.); and polyphenyl sulfide films such as TORELINA (trade name, manufactured by Toray Industries, Inc.). From the viewpoints of easy availability, heat resistance (preferably at 100° C. or higher), economic efficiency, and effectiveness, commercially available polyethylene terephthalate, polyethylene naphthalate, a variety of polyimides or polycarbonate films, and the like are preferred.

The base material is preferably used after being provided with the electrode on the surface that is pressure-bonded to the thermoelectric conversion layer. As an electrode material forming the first electrode and the second electrode that are provided on the base material, it is possible to use a transparent electrode of ITO, ZnO, or the like; a metal electrode of silver, copper, gold, aluminum, or the like; a carbon material such as CNT or graphene; an organic material such as PEDOT/PSS; an electroconductive paste obtained by dispersing electroconductive fine particles of silver, carbon, or the like; and an electroconductive paste containing a metal nanowire of silver, copper, aluminum, or the like. Among these, a metal electrode of silver, copper, gold, aluminum, or the like or an electroconductive paste containing the above-described metal is preferred.

From the viewpoint of handling properties, durability, and the like, the thickness of the base material is preferably 30 μm to 3,000 μm, more preferably 50 μm to 1,000 μm, still more preferably 100 μm to 1,000 μm, and particularly preferably 200 μm to 800 μm. When the thickness of the base material is set in this range, the thermal conductivity does not decrease, and the thermoelectric conversion layer is not easily damaged due to an external impact.

The layer thickness of the thermoelectric conversion layer is preferably 0.1 μm to 1,000 μm and more preferably 0.5 μm to 100 μm. When the film thickness is set in this range, it is easy to apply a temperature difference, and an increase in the resistance in the film can be prevented.

Generally, the thermoelectric conversion element can be simply manufactured compared with a photoelectric conversion element such as an organic thin film solar cell element. Particularly, when the thermoelectric conversion material of the invention is used, compared with an organic thin film solar cell element, it is not necessary to consider the light absorption efficiency, and thus it is possible to increase the thickness by approximately 100 times to 1,000 times, and the chemical stability with respect to oxygen or moisture in the air improves.

A method for forming the thermoelectric conversion layer is not particularly limited, and, for example, a known coating method such as spin coating, extrusion die coating, blade coating, bar coating, screen printing, stencil printing, roll coating, curtain coating, spray coating, or dip coating can be used. Among these, screen printing is particularly preferred since the adhesiveness of the thermoelectric conversion layer to the electrode is excellent.

After the formation of the film, it is preferable to carry out a drying step as necessary, thereby removing the solvent. For example, the solvent can be volatilized and dried by heating and drying the thermoelectric conversion material or blowing hot air.

In addition, after the formation of the thermoelectric conversion layer, it is preferable to carry out a treatment for decomposing the dispersing agent included in the thermoelectric conversion layer.

As described above, the dispersing agent of the invention has the decomposable group that decomposes due to heat or an acid, and the dispersing agent is decomposed by means of heating or an acid treatment. When the dispersing agent is decomposed after or while the thermoelectric conversion layer is formed, a carrier path is built between the nanocarbon material particles, and the migration and diffusion of charges is promoted, and thus the electroconductive properties and the thermoelectromotive force of the thermoelectric conversion layer improve. That is, the thermoelectric conversion material of the invention is capable of exhibiting excellent coating and film-forming properties in a state in which the dispersing agent is not decomposed since the nanocarbon material is favorably dispersed and is capable of further improving the thermoelectric conversion performance since the dispersing agent is decomposed after the formation of the thermoelectric conversion layer.

As the treatment for decomposing the dispersing agent, a heating treatment or an acid treatment is preferably carried out on the thermoelectric conversion layer, and a heating treatment is more preferably carried out. The heating treatment is carried out at preferably 80° C. or higher, more preferably 100° C. or higher, or still more preferably 120° C. or higher for preferably one minute or longer and more preferably 10 minutes or longer. The heating treatment can be carried out together with the above-described solvent removal treatment. In addition, in the acid treatment, the thermoelectric conversion layer may be immersed in an acid solution, or it is also possible to add an acid-generating agent to the thermoelectric conversion material and generate an acid by heating the acid-generating agent after the formation of the thermoelectric conversion layer.

The thermoelectric conversion element of the invention exhibits excellent thermoelectric conversion performance and can be preferably used as a power generating element for a thermoelectric power generating component. Specific examples of the power generating element include electric power generators such as a hot spring electrical heat generator, a solar heat power generator, and a waste heat power generator, a power supply for a wrist watch, a semiconductor-driven power supply, and a power supply for a (small-sized) sensor.

[Nanocarbon Material Dispersion]

A composition of the invention is a nanocarbon material dispersion obtained by containing the above-described nanocarbon material and the dispersing agent of the invention. The composition may contain other components, and the components can be appropriately selected depending on the applications. Examples of the other components include a solvent, a resin, and a variety of additives. Among these, the composition preferably contains a solvent.

In addition, the dispersing agent and the nanocarbon material dispersion of the invention can be preferably used not only for the thermoelectric conversion material or the thermoelectric conversion element but also for a variety of electroconductive materials or electroconductive components.

### EXAMPLES

Hereinafter, the present invention will be explained in more detail by way of Examples, but the invention is not intended to be limited to these.

Dispersing agents used in the examples will be described below. In the following chemical formulae, the numbers of individual repeating units represent mole %. The molecular weights of these dispersing agents are as described below. The weight-average molecular weight was measured using gel permeation chromatography (GPC).

Dispersing agent 1: Weight-average molecular weight=21,000

Dispersing agent 2: Weight-average molecular weight=19,000

Dispersing agent 3: Weight-average molecular weight=29,000

Dispersing agent 4: Weight-average molecular weight=32,000

Dispersing agent 5: Weight-average molecular weight=18,000

Dispersing agent c1: Weight-average molecular weight=20,000

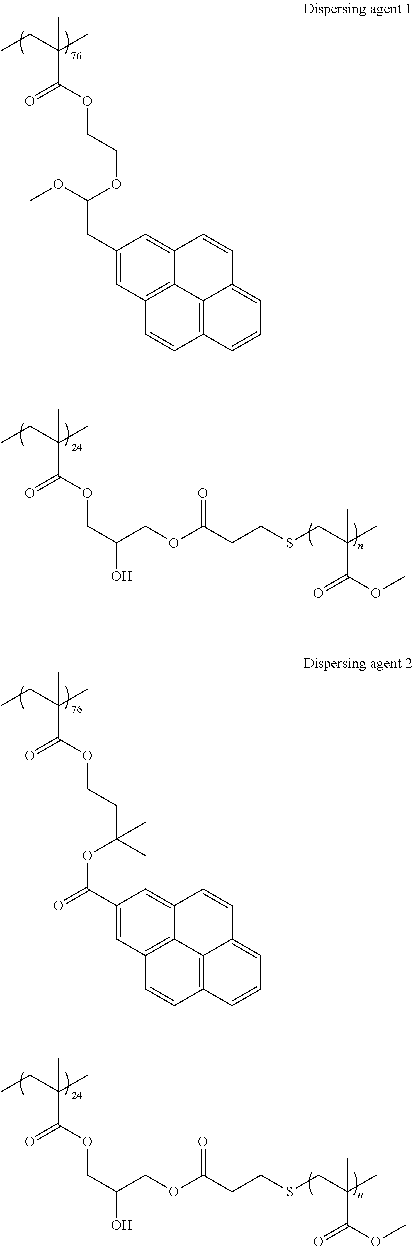

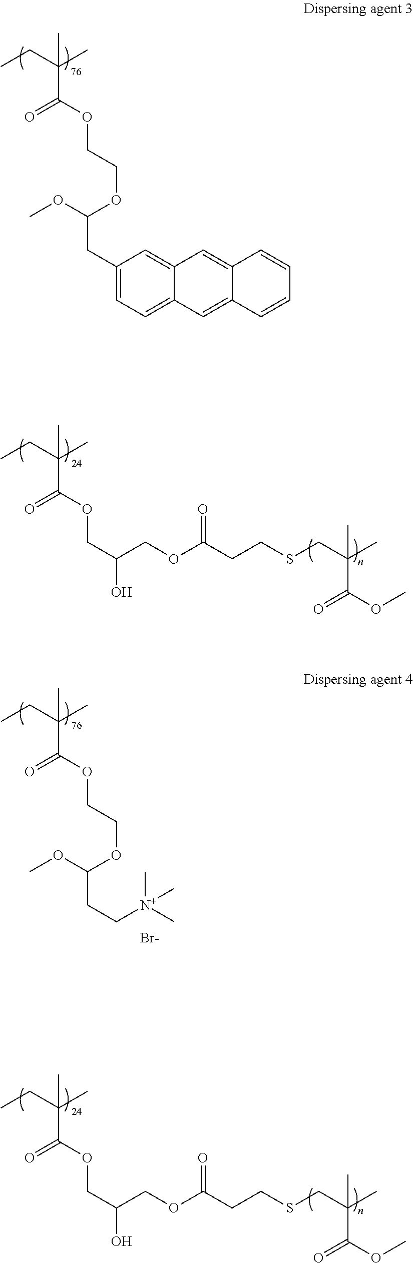

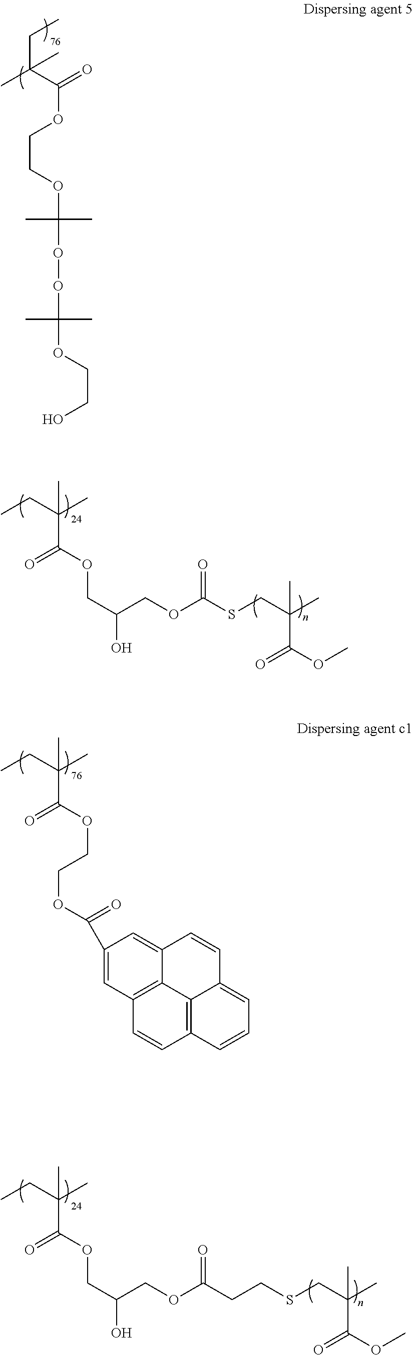

Synthesis of Macromonomer of Polymethyl Methacrylate (PMMA)

100 g of methyl methacrylate and 0.35 g of thiopropionic acid were injected into a 250 mL three-neck flask and were heated to 80° C. After the heating, 17 mg of azobisisobutyronitrile (AIBN, manufactured by Wako Pure Chemical Industries, Ltd.) was injected thereinto and was reacted for 40 minutes, and then, repeatedly, 17 mg of AIBN (manufactured by Wako Pure Chemical Industries, Ltd.) was injected thereinto and was reacted for 40 minutes twice. After that, 10 g of tetrahydrofuran was injected thereinto, thereby ending the reaction. The reaction liquid was precipitated again, thereby obtaining 60 g of an intermediate body A.

15 g of the obtained intermediate body A, 30 g of xylene, 0.28 g of glycidyl methacrylate, 0.01 g of hydroquinone, and 0.01 g of dimethyl laurylamine were injected into a 250 mL three-neck flask and were reacted for five hours under reflux conditions. After that, the reaction liquid was precipitated again, thereby obtaining 10 g of a macromonomer of polymethyl methacrylate (PMMA).

### Synthesis Example 1

### Synthesis of Dispersing Agent 1

10 g of the following compound 1A and 4.1 g of acetyl chloride were injected into a 300 mL three-neck flask and were reacted at 45° C. for four hours. After the reaction, the components were dried at a reduced pressure, thereby obtaining 8 g of an intermediate body 1A.

Next, 8 g of the obtained intermediate body 1A, 6.7 g of hydroxyethyl methacrylate, 16 g of tetrahydrofuran, 8 g of propylene glycol monomethyl ether acetate, and 5 g of triethylamine were injected into a 300 mL three-neck flask and were reacted at room temperature for six hours. After the reaction, 30 g of chloroform was injected thereinto, the solvent was distilled away after sodium bicarbonate water washing and water washing, and the components were purified by means of column chromatography, thereby obtaining 4 g of a target monomer 1.

0.8 g of the monomer 1 obtained above, 4 g of the macromonomer of PMMA synthesized above, and 8 g of dimethyl acetamide were injected into a 250 mL three-neck flask and were heated to 80° C. After that, 0.0127 g of a polymerization initiator V-601 (manufactured by Wako Pure Chemical Industries, Ltd.) was injected thereinto and was reacted for two hours. Furthermore, a step of injecting 0.0127 g of V-601 (manufactured by Wako Pure Chemical Industries, Ltd.) and reacting V-601 for two hours was repeated twice. The obtained reaction liquid was precipitated again, thereby obtaining 3 g of a target polymer 1 (dispersing agent 1).

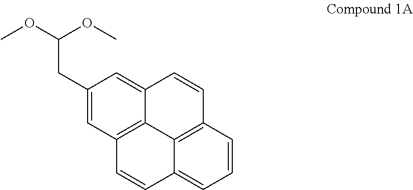 [SMILES: COC(Cc1cc2ccc3cccc4ccc(c1)c2c34)OC]

### Synthesis Example 2

### Synthesis of Dispersing Agent 2

15 g of 3-methyl-3-butenyl methacrylate, 50 g of 1-carboxylic pyrene, 50 mL of dichloromethane, and 1 g of methane sulfonic acid were injected into a 300 mL three-neck flask and were reacted at room temperature for 12 hours. After the reaction, 30 g of chloroform was injected thereinto, the solvent was distilled away after sodium bicarbonate water washing and water washing, and the components were purified by means of column chromatography, thereby obtaining 10 g of a target monomer 2.

0.8 g of the monomer 2 obtained above, 4 g of the macromonomer of PMMA synthesized above, and 8 g of dimethyl acetamide were injected into a 250 mL three-neck flask and were heated to 80° C. After that, 0.0127 g of a polymerization initiator V-601 (manufactured by Wako Pure Chemical Industries, Ltd.) was injected thereinto and was reacted for two hours. Furthermore, a step of injecting 0.0127 g of V-601 (manufactured by Wako Pure Chemical Industries, Ltd.) and reacting V-601 for two hours was repeated twice. The obtained reaction liquid was precipitated again, thereby obtaining 3 g of a target polymer 2 (dispersing agent 2).

### Synthesis Example 3

### Synthesis of Dispersing Agent 3

9 g of the following compound 3A and 4.1 g of acetyl chloride were injected into a 300 mL three-neck flask and were reacted at 45° C. for four hours. After the reaction, the components were dried at a reduced pressure, thereby obtaining 8 g of an intermediate body 3A.

Next, 8 g of the obtained intermediate body 3A, 6.7 g of hydroxyethyl methacrylate, 16 g of tetrahydrofuran, 8 g of propylene glycol monomethyl ether acetate, and 5 g of triethylamine were injected into a 300 mL three-neck flask and were reacted at room temperature for six hours. After the reaction, 30 g of chloroform was injected thereinto, the solvent was distilled away after sodium bicarbonate water washing and water washing, and the components were purified by means of column chromatography, thereby obtaining 5 g of a target monomer 3.

0.8 g of the monomer 3 obtained above, 4 g of the macromonomer of PMMA synthesized above, and 8 g of dimethyl acetamide were injected into a 250 mL three-neck flask and were heated to 80° C. After that, 0.0127 g of a polymerization initiator V-601 (manufactured by Wako Pure Chemical Industries, Ltd.) was injected thereinto and was reacted for two hours. Furthermore, a step of injecting 0.0127 g of V-601 (manufactured by Wako Pure Chemical Industries, Ltd.) and reacting V-601 for two hours was repeated twice. The obtained reaction liquid was precipitated again, thereby obtaining 4 g of a target polymer 3 (dispersing agent 3).

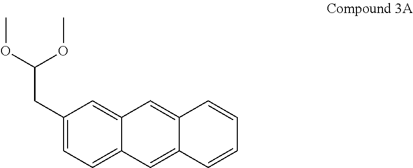 [SMILES: COC(Cc1ccc2cc3ccccc3cc2c1)OC]

### Synthesis Example 4

### Synthesis of Dispersing Agent 4

8 g of the following compound 4A and 5 g of acetyl chloride were injected into a 300 mL three-neck flask and were reacted at 45° C. for four hours. After the reaction, the components were dried at a reduced pressure, thereby obtaining 8 g of an intermediate body 4A.

Next, 8 g of the obtained intermediate body 4A, 7 g of hydroxyethyl methacrylate, 16 g of tetrahydrofuran, 8 g of propylene glycol monomethyl ether acetate, and 7 g of triethylamine were injected into a 300 mL three-neck flask and were reacted at room temperature for six hours. After the reaction, 30 g of chloroform was injected thereinto, the solvent was distilled away after sodium bicarbonate water washing and water washing, and the components were purified by means of column chromatography, thereby obtaining 4 g of a target monomer 4.

0.8 g of the monomer 4 obtained above, 4 g of the macromonomer of PMIVIA synthesized above, and 8 g of dimethyl acetamide were injected into a 250 mL three-neck flask and were heated to 80° C. After that, 0.0127 g of a polymerization initiator V-601 (manufactured by Wako Pure Chemical Industries, Ltd.) was injected thereinto and was reacted for two hours. Furthermore, a step of injecting 0.0127 g of V-601 (manufactured by Wako Pure Chemical Industries, Ltd.) and reacting V-601 for two hours was repeated twice. The obtained reaction liquid was precipitated again, thereby obtaining 3 g of a target polymer 4 (dispersing agent 4).

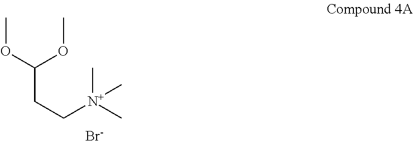

### Synthesis Example 5

### Synthesis of Dispersing Agent 5

24 g of the following compound 5A, 19 g of 1-ethyl-3-(3-dimethylaminopropyl)carbodiimide hydrochloride, 50 mL of dichloromethane, and 8 g of methacrylic acid were injected into a 300 mL three-neck flask and were reacted at room temperature for four hours. After the reaction, 30 g of chloroform was injected thereinto, the solvent was distilled away after sodium bicarbonate water washing and water washing, and the components were purified by means of column chromatography, thereby obtaining 10 g of a target monomer 5.

0.8 g of the monomer 5 obtained above, 4 g of the macromonomer of PMMA synthesized above, and 8 g of dimethyl acetamide were injected into a 300 mL three-neck flask and were heated to 30° C. After that, 0.025 g of a polymerization initiator V-70 (manufactured by Wako Pure Chemical Industries, Ltd.) was injected thereinto and was reacted for two hours. Furthermore, a step of injecting 0.025 g of V-70 (manufactured by Wako Pure Chemical Industries, Ltd.) and reacting V-70 for two hours was repeated twice. The obtained reaction liquid was precipitated again, thereby obtaining 3 g of a target polymer 5 (dispersing agent 5).

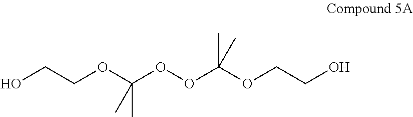 [SMILES: CC(C)(OCCO)OOC(C)(C)OCCO]

### Synthesis Example 6

### Synthesis of Dispersing Agent c1

25 g of 1-carboxylic pyrene, 19 g of 1-ethyl-3-(3-dimethylaminopropyl)carbodiimide hydrochloride, 50 mL of dichloromethane, and 14 g of 2-hydroxyethyl methacrylate were injected into a 300 mL three-neck flask and were reacted at room temperature for four hours. After the reaction, 30 g of chloroform was injected thereinto, the solvent was distilled away after sodium bicarbonate water washing and water washing, and the components were purified by means of column chromatography, thereby obtaining 12 g of a target monomer c1.

0.8 g of the monomer c1 obtained above, 4 g of the macromonomer of PMMA synthesized above, and 8 g of dimethyl acetamide were injected into a 300 mL three-neck flask and were heated to 80° C. After that, 0.0127 g of a polymerization initiator V-601 (manufactured by Wako Pure Chemical Industries, Ltd.) was injected thereinto and was reacted for two hours. Furthermore, a step of injecting 0.0127 g of V-601 (manufactured by Wako Pure Chemical Industries, Ltd.) and reacting V-601 for two hours was repeated twice. The obtained reaction liquid was precipitated again, thereby obtaining 3 g of a target polymer c1 (dispersing agent c1).

### Example 1

Thermoelectric Conversion Element 101

5 mg of the dispersing agent 1 and 5 mg of a single-layer CNT (manufactured by KH Chemicals) were added to 10 ml of ortho-dichlorobenzene and were dispersed using an ultrasonic homogenizer for 20 minutes, thereby preparing a dispersion liquid 101.

As a base material, a glass substrate having a thickness of 1.1 mm and a size of 40 mm×50 mm was used. After this base material was ultrasonic-washed in acetone, a UV-ozone treatment was carried out for 10 minutes. After that, gold pieces having a size of 30 mm×5 mm and a thickness of 10 nm were respectively formed on both end part sides of the base material as a first electrode and a second electrode.

A TEFLON (registered trademark) frame was attached onto the base material on which the electrodes were formed, the prepared dispersion liquid 101 was poured into the frame and was dried on a hot plate at 60° C. for one hour, the frame was removed after the drying, furthermore, the dispersion liquid was heated at 150° C. for one hour in order to decompose a dispersing agent so as to form a thermoelectric conversion layer having a thickness of approximately 1.1 μm, thereby producing a thermoelectric conversion element 101 having the constitution illustrated in FIG. 1.

Dispersion liquids 102 to 105 and c101 and thermoelectric conversion elements 102 to 105 and c101 were produced in the same manner as the dispersion liquid 101 and the thermoelectric conversion element 101, except that the dispersing agents shown in Table 1 were used instead of the dispersing agent 1.

The change in the dispersibility of the dispersion liquid while being heated and the electrical conductivity and the thermoelectromotive force of the thermoelectric conversion element were evaluated using the following methods.

[Change in Dispersibility While Being Heated]

The dispersion liquid was heated at 50° C. for 10 minutes, and the sedimentation property of the nanocarbon material was evaluated using the following standards.

A: The sedimentation of the nanocarbon material was visually confirmed.

B: The sedimentation of the nanocarbon material was not visually confirmed.

[Thermoelectromotive Force and Electrical Conductivity]

The first electrode of each thermoelectric conversion element was disposed on a hot plate maintained at a constant temperature, and a Peltier device for temperature control was disposed on the second electrode.

While the temperature of the hot plate was maintained constant (100° C.), the temperature of the Peltier device was decreased, and thereby a temperature difference (in the range of more than 0 K but no more than 4 K) was applied between the two electrodes.

At this time, the thermoelectromotive force (μV) generated between the two electrodes was divided by the particular temperature difference (K) generated between the two electrodes, and thereby the thermoelectromotive force S per unit temperature difference (μV/K) was calculated. In addition, simultaneously, the electrical conductivity (S/cm) was calculated by measuring an electrical current generated between the two electrodes.

TABLE 1

| | | Change in | | | |
|---|---|---|---|---|---|
| Thermoelectric | | dispersibility | Electrical | Thermoelectromotive | |
| conversion | Dispersing | while being | conductivity | force S | |
| element | agent | heated | (S/cm) | (μV/K) | Note |
| 101 | 1 | A | 550 | 30 | Present |
| | | | | | Invention |
| 102 | 2 | A | 560 | 31 | Present |
| | | | | | Invention |
| 103 | 3 | A | 520 | 35 | Present |
| | | | | | Invention |
| 104 | 4 | A | 480 | 28 | Present |
| | | | | | Invention |
| 105 | 5 | A | 470 | 27 | Present |
| | | | | | Invention |
| c101 | c1 | B | 330 | 20 | Reference |
| | | | | | example |

As is clear from Table 1, in the CNT dispersion liquids 101 to 105 for which the dispersing agents 1 to 5 having the decomposable group were used, the dispersibility was changed due to heating. On the other hand, in the dispersion liquid for which the dispersing agent cl not having the decomposable group was used, the dispersibility was not changed due to heating.

Furthermore, in the thermoelectric conversion elements 101 to 105 for which the dispersing agents 1 to 5 were used, compared with the thermoelectric conversion element c101 for which the dispersing agent c1 not having the decomposable group was used, a higher electrical conductivity and a higher thermoelectromotive force were exhibited.

### Example 2

### Nanocarbon Material Other than CNT

A thermoelectric conversion element 201 was prepared in the same manner as the thermoelectric conversion element 101, except that the nanocarbon material was changed from CNT to a graphitized mesoporous carbon (manufactured by Sigma-Aldrich Co. LCC.).

In addition, a thermoelectric conversion element c201 was prepared in the same manner as the thermoelectric conversion element c101, except that the nanocarbon material was changed from CNT to a graphitized mesoporous carbon (manufactured by Sigma-Aldrich Co. LCC.).

For these thermoelectric conversion elements, the dispersibility, the electrical conductivity, and the thermoelectromotive force were evaluated in the same manner as in Example 1. The results are shown in Table 2.

TABLE 2

| | | Change in | | | |
|---|---|---|---|---|---|
| Thermoelectric | | dispersibility | Electrical | Thermoelectromotive | |
| conversion | Dispersing | while being | conductivity | force S | |
| element | agent | heated | (S/cm) | (μV/K) | Note |
| 201 | 1 | A | 130 | 25 | Present |
| | | | | | Invention |
| c201 | c1 | B | 80 | 18 | Reference |
| | | | | | example |

As is clear from Table 2, even in case in which a nanocarbon material other than CNT was used, in a CNT dispersion liquid 201 for which the dispersing agent 1 having the decomposable group was used, the dispersibility was changed due to heating. On the other hand, in the dispersion liquid for which the dispersing agent cl not having the decomposable group was used, the dispersibility was not changed due to heating.

Furthermore, in the thermoelectric conversion element 201 for which the dispersing agent 1 was used, compared with the thermoelectric conversion element c201 for which the dispersing agent cl not having the decomposable group was used, a higher electrical conductivity and a higher thermoelectromotive force were exhibited.

The invention has been explained together with the examples, but the present inventors do not intend to limit the invention in any detailed parts of the explanation unless particularly otherwise described and consider that the invention should be widely interpreted within the spirit and scope of the invention described in the accompanying claims.

### EXPLANATION OF REFERENCES

1, 2: Thermoelectric conversion element

11, 17: Metal plate

12, 22: First base material

13, 23: First electrode

14, 24: Thermoelectric conversion layer

15, 25: Second electrode

16, 26: Second base material

What is claimed is:

1. A thermoelectric conversion material comprising:
(a) a nanocarbon material; and
(b) a dispersing agent having an anchoring group to the nanocarbon material and a steric repulsive group and having a decomposable group between the anchoring group and the steric repulsive group.

2. The thermoelectric conversion material according to claim 1,
wherein (b) the dispersing agent is a polymer compound including a repeating unit represented by General Formula (1A) below and a repeating unit represented by General Formula (1B) below: 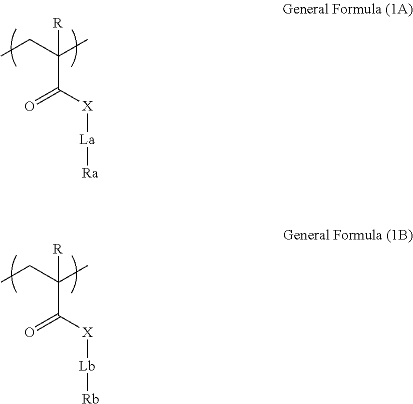
in General Formula (1A), Ra represents an aromatic group, an alicyclic group, an alkyl group, a hydroxyl group, a thiol group, an amino group, an ammonium group, or a carboxyl group; La represents a divalent group having an acetal structure, a tertiary alkyl ester structure, or a peroxide structure; R represents a hydrogen atom or an alkyl group having 1 to 4 carbon atoms; and X represents an oxygen atom or —NH—, and
in General Formula (1B), Rb represents a monovalent group derived from a polyalkylene oxide compound, a poly(meth)acrylate compound, a polysiloxane compound, a polyacrylonitrile compound, or a polystyrene compound, a monovalent group obtained by combining the above-described compounds, or an alkyl group having 5 or more carbon atoms; Lb represents a single bond or a divalent linking group; and R and X are identical to those in General Formula (1A).

3. The thermoelectric conversion material according to claim 1, wherein (b) the dispersing agent is a compound represented by General Formula (2) below:
RaₙLₘRb General Formula (2)
in General Formula (2), Ra represents an aromatic group, an alicyclic group, an alkyl group, a hydroxyl group, a thiol group, an amino group, an ammonium group, or a carboxyl group; Rb represents a monovalent group derived from a polyalkylene oxide compound, a poly(meth)acrylate compound, a polysiloxane compound, a polyacrylonitrile compound, or a polystyrene compound, a monovalent group obtained by combining the above-described compounds, or an alkyl group having 5 or more carbon atoms; L represents a (n+m)-valent organic group having an acetal structure, a tertiary alkyl ester structure, or a peroxide structure; and each of n and m independently represents an integer of 1 to 4.

4. The thermoelectric conversion material according to claim 2,
wherein, in General Formula (1A) or General Formula (2), Ra is an aromatic group.

5. The thermoelectric conversion material according to claim 2,
wherein, in General Formula (1B) or General Formula (2), Rb is a monovalent group derived from a poly(meth)acrylate compound.

6. The thermoelectric conversion material according to claim 1, comprising:
a solvent.

7. A thermoelectric conversion element comprising, on a base material:
a first electrode;
a thermoelectric conversion layer; and
a second electrode,
wherein the thermoelectric conversion layer is formed using the thermoelectric conversion material according to claim 1.

8. A method for manufacturing a thermoelectric conversion element, comprising:
a step of forming a thermoelectric conversion layer on a base material by applying the thermoelectric conversion material according to claim 1; and
a step of decomposing a dispersing agent in the formed thermoelectric conversion layer.

9. The method for manufacturing a thermoelectric conversion element according to claim 8,
wherein, in the decomposition step, a heating treatment of the thermoelectric conversion layer is carried out.

10. A nanocarbon material dispersion comprising:
(a) a nanocarbon material;
(b1) a polymer compound including a repeating unit represented by General Formula (1A) below and a repeating unit represented by General Formula (1B) below; and
(c) a solvent: 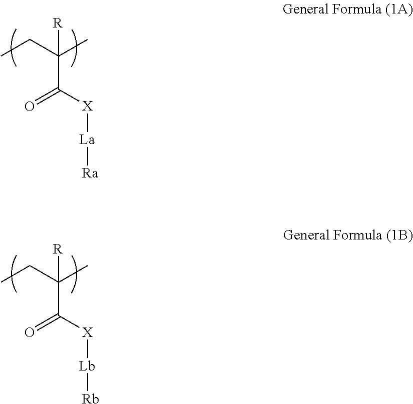
in General Formula (1A), Ra represents an aromatic group, an alicyclic group, an alkyl group, a hydroxyl group, a thiol group, an amino group, an ammonium group, or a carboxyl group; La represents a divalent group having an acetal structure, a tertiary alkyl ester structure, or a peroxide structure; R represents a hydrogen atom or an alkyl group having 1 to 4 carbon atoms; and X represents an oxygen atom or —NH—, and
in General Formula (1B), Rb represents a monovalent group derived from a polyalkylene oxide compound, a poly(meth)acrylate compound, a polysiloxane compound, a polyacrylonitrile compound, or a polystyrene compound, a monovalent group obtained by combining the above-described compounds, or an alkyl group having 5 or more carbon atoms; Lb represents a single bond or a divalent linking group; and R and X are identical to those in General Formula (1A).

11. A dispersing agent of a nanocarbon material made of a polymer compound including a repeating unit represented by General Formula (1A) below and a repeating unit represented by General Formula (1B) below: 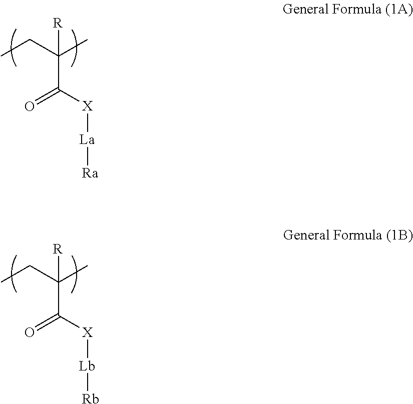
in General Formula (1A), Ra represents an aromatic group, an alicyclic group, an alkyl group, a hydroxyl group, a thiol group, an amino group, an ammonium group, or a carboxyl group; La represents a divalent group having an acetal structure, a tertiary alkyl ester structure, or a peroxide structure; R represents a hydrogen atom or an alkyl group having 1 to 4 carbon atoms; X represents an oxygen atom or —NH—;
in General Formula (1B), Rb represents a monovalent group derived from a polyalkylene oxide compound, a poly(meth)acrylate compound, a polysiloxane compound, a polyacrylonitrile compound, or a polystyrene compound, a monovalent group obtained by combining the above-described compounds, or an alkyl group having 5 or more carbon atoms; Lb represents a single bond or a divalent linking group; R and X are identical to those in General Formula (1A).
